(19) United States
(12) Patent Application Publication
(10) Pub. No.: US 2026/0101698 A1
(43) Pub. Date: Apr. 9, 2026

(54) SUBSTRATE PROCESSING APPARATUS

(71) Applicant: SCREEN HOLDINGS CO., LTD., Kyoto (JP)

(72) Inventors: Shuhei NEMOTO, Kyoto (JP); Kazuhiro SHOJI, Kyoto (JP); Tomohiro UEMURA, Kyoto (JP); Yusuke SATO, Kyoto (JP); Norimasa MATSUI, Kyoto (JP)

(21) Appl. No.: 19/114,272

(22) PCT Filed: Jul. 24, 2023
(86) PCT No.: PCT/JP2023/026934

§ 371 Date: Mar. 21, 2025

(30) Foreign Application Priority Data
Sep. 21, 2022 (JP) 2022-149719

(51) Int. Cl. H10P 72/00; H10P 72/76; H10P 72/78

(52) U.S. Cl. CPC H10P 72/0421; H10P 72/78; H10P 72/7616

(57) ABSTRACT

The present invention has an upper surface protecting/heating mechanism that heats a substrate while covering an upper surface of the substrate held by the substrate holder. In the upper surface protecting/heating mechanism, a base block, a first under block and a second under block are combined to form a clearance region and an annular air outlet. Gas flowing in the clearance region is heated by a peripheral edge heating part and then supplied from the annular air outlet to the vicinity of the peripheral edge part of the upper surface of the substrate. The peripheral edge heating part heats not only the peripheral edge part of the upper surface of the substrate but also the peripheral edge part of the substrate to a temperature suitable for the substrate processing in a short time.

### TECHNICAL FIELD

This invention relates to a substrate processing apparatus for processing a peripheral edge part of a substrate with a processing liquid. Herein, the substrate includes a semiconductor wafer, a glass substrate for liquid crystal display, a glass substrate for plasma display, an optical disk substrate, a magnetic disk substrate, a magneto-optical disk substrate, a glass substrate for photomask, a substrate for solar battery, and the like (hereinafter, referred to simply as a “substrate”). Further, the processing includes an etching process.

The disclosure of Japanese Patent Application described below including specification, drawings and claims is incorporated herein by reference in its entirety.

Japanese Patent Application No. 2022-149719 (filed on Sep. 21, 2022)

### BACKGROUND

As a substrate processing apparatus for performing chemical liquid processing, cleaning processing, or the like on a substrate such as a semiconductor wafer or the like by supplying a processing liquid to a peripheral edge part of the substrate while rotating the substrate, well known is, for example, an apparatus described in Patent Literature 1. In this substrate processing apparatus, the substrate is held horizontally by a spin chuck, and as an auxiliary mechanism used in that case, a gas supply unit is provided. This gas supply unit has a shielding plate with a lower surface thereof facing an upper surface of the substrate. At a central part of the shielding plate, a nozzle is provided. Then, a gas such as a nitrogen gas or the like is supplied from the nozzle toward a central part of the upper surface of the substrate.

### CITATION LIST

### Patent Literature

[Patent Literature 1] Japanese Patent Application Laid Open Gazette No. 2022-34285 (FIGS. 6, 7, and the like).

### SUMMARY

### Technical Problem

Thus, in order to increase the operation efficiency in bevel processing, for example, for processing the peripheral edge part of the substrate, it is necessary to raise a temperature of the peripheral edge part of the substrate to a desired temperature. Then, in the above-described background-art apparatus, proposed is a technique for supplying a heated gas from the nozzle of the shielding plate (proposed technique). The heated gas supplied from the nozzle is, however, first supplied to a central part of the upper surface of the substrate and then supplied to the peripheral edge part along the upper surface of the substrate. For this reason, the gas having a temperature higher than room temperature is not always supplied to the peripheral edge part of the substrate efficiently and the amount of usage of the heated gas disadvantageously increases. In other words, the background-art substrate processing apparatus has room for improvement in terms of reduction in the environmental load. Further, as the amount of usage of the heated gas increases, a lot of electric power required to heat the gas is consumed, and there is also room for improvement in terms of reduction in the power consumption.

This invention is intended to solve the above-described problem, and in the substrate processing apparatus for performing substrate processing on a peripheral edge part of a substrate whose temperature is raised by the heated gas by supplying a processing liquid to the peripheral edge part, it is an object of this invention to ensure reduction in the environmental load by reducing the amount of usage of the heated gas.

### Solution to Problem

This invention is directed to a substrate processing apparatus. The apparatus comprises: a substrate holder provided rotatably about an axis of rotation extending in a vertical direction while holding a substrate in a substantially horizontal posture; a rotating mechanism configured to rotate the substrate holder about the axis of rotation; a processing mechanism configured to perform substrate processing on a peripheral edge part of the substrate by supplying a processing liquid to a peripheral edge part of an upper surface of the substrate held by the substrate holder rotated by the rotating mechanism; and an upper surface protecting/heating mechanism configured to heat the substrate while being configured to cover the upper surface of the substrate held by the substrate holder, wherein the upper surface protecting/heating mechanism includes: a base block in which a first opening is provided at a central part of an upper surface thereof, a second opening wider than the first opening is provided at a central part of an upper surface thereof, and a funnel-like space having an inner diameter which becomes larger as it goes downward from the first opening and is connected to the second opening; a first under block, in which a third opening having the same shape as the second opening is provided with at a central part of an upper surface thereof, and a penetration space is formed so as to penetrate from the third opening toward a central part of a lower surface thereof and has a hollow shape, being coupled to the base block in a state where the third opening coincides with the second opening and a lower surface of a peripheral edge part thereof faces the peripheral edge part of the upper surface of the substrate; a peripheral edge heating part provided in the first under block; and a second under block coupled to the base block with the lower surface thereof facing a central part of the upper surface of the substrate while being loosely inserted into the penetration space and the funnel-like space, an annular air outlet formed between the lower surface of the first under block and the lower surface of the second under block in the vicinity of the peripheral edge part of the upper surface of the substrate is connected to the first opening through a clearance region between the base block and the first under block and the second under block, and the peripheral edge heating part heats the gas flowing in the clearance region and heats the peripheral edge part of the upper surface of the substrate.

In the invention having such a configuration, the annular air outlet is formed in the vicinity of the peripheral edge part of the upper surface of the substrate, and the heated gas is directly supplied from the annular air outlet to the vicinity of the peripheral edge part of the substrate. For this reason, in the present invention, it is possible to more efficiently raise the temperature of the peripheral edge part of the substrate than in the proposed technique which raises the temperature of the peripheral edge part of the substrate by causing the heated gas supplied to the central part of the upper surface of the substrate to flow to the peripheral edge part of the substrate along the upper surface of the substrate. Therefore, it is possible to heat the peripheral edge part of the substrate with the heated gas which is less than that in the proposed technique.

Further, by efficiently raising the temperature of the substrate, the processing capability is increased, in other words, the processing time is reduced. As a result, the amount of chemical liquid to be used can be reduced, and the environmental load is thereby reduced.

Furthermore, in the present invention, as a heating means for heating the gas flowing in the clearance region, the peripheral edge heating part is provided in the first under block. Specifically, the gas is heated immediately before being supplied from the annular air outlet. For this reason, the high-temperature heated gas is supplied from the annular air outlet to the peripheral edge part of the upper surface of the substrate. Moreover, the peripheral edge part of the upper surface of the substrate is heated by not only the above-described heated gas but also the peripheral edge heating part. Therefore, as compared with the proposed technique, it is possible to raise the temperature of the peripheral edge part of the substrate to a temperature suitable for the substrate processing in a short time.

Further, the term “to loosely insert” in the specification means “to insert” something in a state where there is a spatial margin. More specifically, this means that a surface of the base block and a surface of the second under block which face the funnel-like space are not in contact with each other and moreover a surface of the first under block and the surface of the second under block which face the penetration space are not in contact with each other.

### Advantageous Effects of Invention

According to this invention, in the substrate processing apparatus for performing substrate processing on the peripheral edge part of the substrate whose temperature is raised by the heated gas, by supplying the processing liquid to the peripheral edge part, it is possible to reduce the amount of heated gas to be used and to thereby reduce the environmental load.

All of a plurality of constituent elements of each aspect of the invention described above are not essential and some of the plurality of constituent elements can be appropriately changed, deleted, replaced by other new constituent elements or have limited contents partially deleted in order to solve some or all of the aforementioned problems or to achieve some or all of effects described in this specification. Further, some or all of technical features included in one aspect of the invention described above can be combined with some or all of technical features included in another aspect of the invention described above to obtain one independent form of the invention in order to solve some or all of the aforementioned problems or to achieve some or all of the effects described in this specification.

### BRIEF DESCRIPTION OF DRAWINGS

FIG. 1 is a plan view showing a schematic configuration of a substrate processing system equipped with a first embodiment of a substrate processing apparatus according to the present invention;

FIG. 2 is a diagram showing a configuration of the first embodiment of the substrate processing apparatus according to the present invention;

FIG. 3 is a diagram schematically showing a configuration of a chamber and a configuration attached to the chamber;

FIG. 4 is a plan view schematically showing a configuration of a substrate processing part installed on a base member;

FIG. 5 is a diagram showing a dimensional relationship between a substrate held on a spin chuck and a rotating cup;

FIG. 6 is a diagram partially showing the rotating cup and a fixed cup;

FIG. 7 is a cross-sectional view showing a configuration of an upper surface protecting/heating mechanism;

FIG. 8 is an exploded view of the upper surface protecting/heating mechanism shown in FIG. 7;

FIG. 9 is a diagram schematically showing a configuration of a nozzle mover; and

FIG. 10 is a flowchart showing bevel processing performed, as an example of a substrate processing operation, by the substrate processing apparatus shown in FIG. 2.

### DESCRIPTION OF EMBODIMENTS

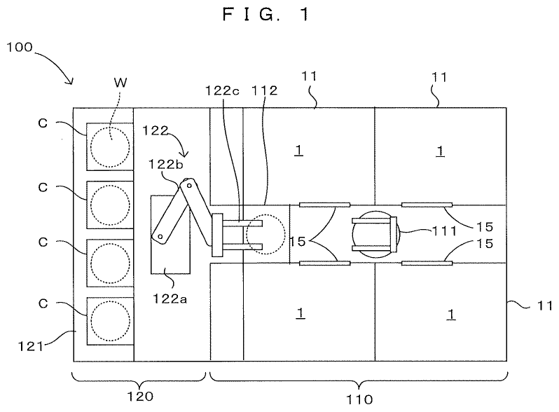

FIG. 1 is a plan view showing a schematic configuration of a substrate processing system equipped with a first embodiment of a substrate processing apparatus according to the present invention. This figure is a diagram not showing the external appearance of a substrate processing system 100, but is a schematic diagram simply showing an internal structure of the substrate processing system 100 by excluding an outer wall panel and other partial configurations. This substrate processing system 100 is, for example, a single-wafer type apparatus installed in a clean room and configured to process substrates W each having a circuit pattern (hereinafter, referred to as a “pattern”) only on one principal surface one by one. Then, substrate processing using a processing liquid is performed in a processing unit 1 equipped in the substrate processing system 100. In the present specification, among both principal surfaces of the substrate, a pattern formation surface (one principal surface) formed with the pattern is referred to as a “front surface” and the other principal surface not formed with the pattern on an opposite side is referred to as a “back surface”. Further, a surface facing down is referred to as a “lower surface” and a surface facing up is referred to as an “upper surface”. Further, in the present specification, the “pattern formation surface” refers to a surface of the substrate where an uneven pattern is formed in an arbitrary region.

Herein, any one of various substrates such as semiconductor wafers, glass substrates for photomask, glass substrates for liquid crystal display, glass substrates for plasma display, substrates for FED (Flat Emission Display), optical disk substrates, magnetic disk substrates, magneto-optical disk substrates, and the like can be applied as the “substrate” in the present embodiment. Although the substrate processing apparatus used in processing semiconductor wafers is mainly described as an example with reference to the drawings below, application to the processing of various substrates illustrated above is also possible.

As shown in FIG. 1, the substrate processing system 100 includes a substrate processing station 110 for processing the substrate W and an indexer station 120 coupled to this substrate processing station 110. The indexer station 120 includes a container holder 121 capable of holding a plurality of containers C for housing the substrates W (FOUPs (Front Opening Unified Pods), SMIF (Standard Mechanical Interface) pods, OCs (Open Cassettes) for housing a plurality of the substrates W in a sealed state), and an indexer robot 122 for taking out an unprocessed substrate W from the container C by accessing the container C held by the container holder 121 and housing a processed substrate W in the container C. A plurality of the substrates W are housed substantially in a horizontal posture in each container C.

The indexer robot 122 includes a base 122a fixed to an apparatus housing, an articulated arm 122b provided rotatably about a vertical axis with respect to the base 122a, and a hand 122c mounted on the tip of the articulated arm 122b. The hand 122c is structured such that the substrate W can be placed and held on the upper surface thereof. Such an indexer robot including the articulated arm and the hand for holding the substrate is not described in detail since being known.

The substrate processing station 110 includes a mounting table 112 on which the indexer robot 122 places the substrate W, a substrate conveyor robot 111 arranged substantially in a center in a plan view and a plurality of processing units 1 arranged to surround this substrate conveyor robot 11. Specifically, the plurality of processing units 1 are arranged to face a space where the substrate conveyor robot 111 is arranged. The substrate conveyor robot 111 randomly accesses the mounting table 112 for these processing units 1 and transfers the substrate W to and from the mounting table 112. On the other hand, each processing unit 1 performs a predetermined processing to the substrate W, and corresponds to the substrate processing apparatus according to the present invention. In the present embodiment, these processing units (substrate processing apparatus) 1 have the same function. Thus, a plurality of the substrates W can be processed in parallel. If the substrate conveyor robot 111 can directly transfer the substrate W from the indexer robot 122, the mounting table 112 is not necessarily required.

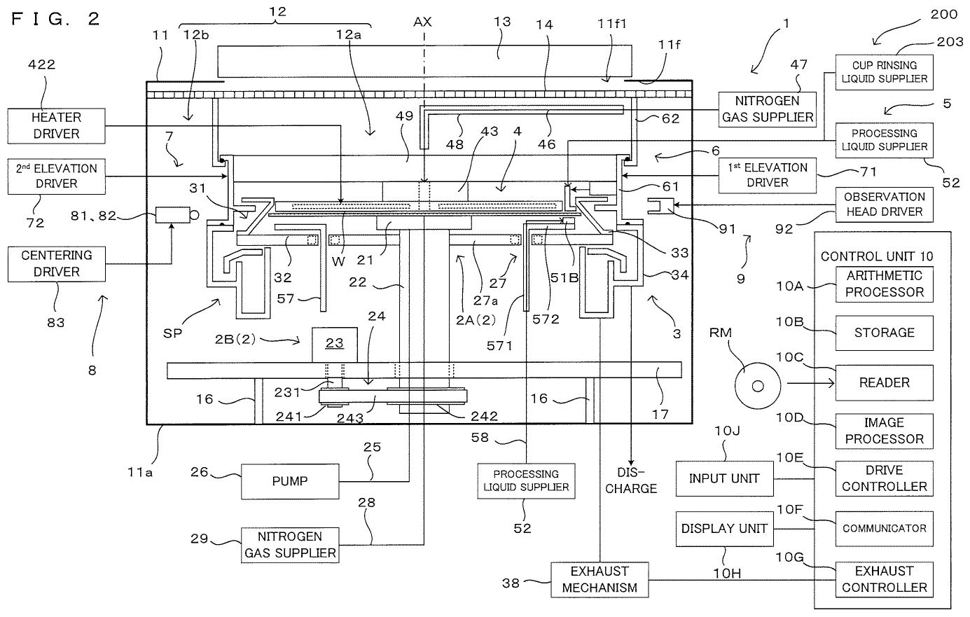

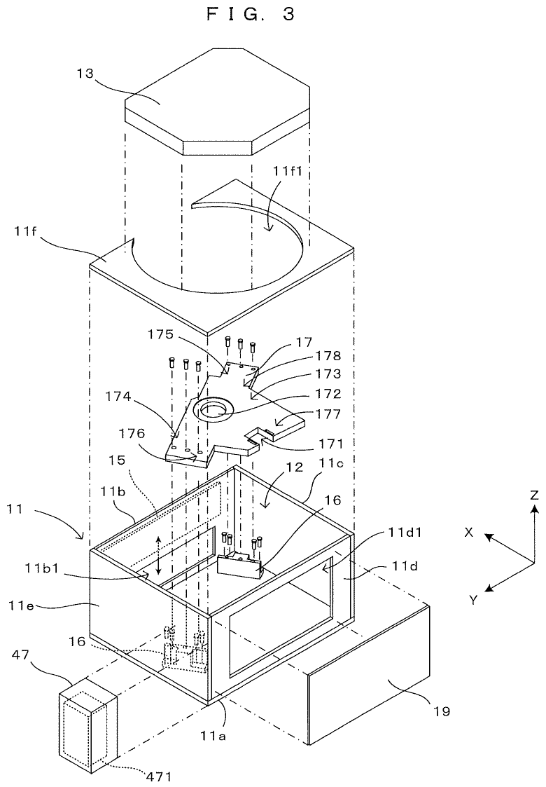

FIG. 2 is a diagram showing a configuration of the first embodiment of the substrate processing apparatus according to the invention. Further, FIG. 3 is a diagram schematically showing a configuration of a chamber and a configuration attached to the chamber. In FIGS. 2 and 3 and each figure to be referred to below, the dimensions and numbers of respective components may be shown in an exaggerated or simplified manner to facilitate understanding. As shown in FIG. 3, a chamber 11 used in the substrate processing apparatus (processing unit) 1 has a bottom wall 11a having a rectangular shape in a plan view vertically from above, four sidewalls 11b to 11e standing from a periphery of the bottom wall 11a, and a ceiling wall 11f covering respective upper end parts of the sidewalls 11b to 11e. By combining the bottom wall 11a, the sidewalls 11b to 11e, and the ceiling wall 11f, formed is an internal space 12 having a substantially rectangular parallelopiped shape.

On an upper surface of the bottom wall 11a, base support members 16 and 16 are fixed away from each other with fastener components such as bolts or the like. Specifically, the base support member 16 stands from the bottom wall 11a. On respective upper end parts of these base support members 16 and 16, a base member 17 is fixed with the fastener components such as bolts or the like. This base member 17 has a plane size smaller than that of the bottom wall 11a and is composed of a metal plate having a thickness larger than that of the bottom wall 11a and rigidity higher than that thereof. As shown in FIG. 2, the base member 17 is raised by the base support members 16 and 16 from the bottom wall 11a vertically upward. In other words, a so-called raised floor structure is formed on a bottom part of the internal space 12 of the chamber 11. As described later, an upper surface of this base member 17 is finished to allow a substrate processing part SP for performing substrate processing on the substrate W to be installed thereon, and the substrate processing part SP is installed on the upper surface thereof. Components constituting this substrate processing part SP are electrically connected to a control unit 10 for controlling the entire apparatus and operate in response to commands from the control unit 10. Further, the shape of the base member 17 and the configuration and operation of the substrate processing part SP will be described later in detail.

As shown in FIGS. 2 and 3, a fan filter unit (FFU) 13 is attached to a ceiling wall 11f of the chamber 11. This fan filter unit 13 further cleans air in a clean room in which the substrate processing apparatus 1 is installed, and supplies the cleaned air into an internal space 12 of the chamber 11. The fan filter unit 13 includes a fan and a filter (e.g. a HEPA (High Efficiency Particulate Air) filter) for taking in the air in the clean room and feeding the air into the chamber 11, and feeds the cleaned air via an opening 11f1 provided in the ceiling wall 11f. In this way, a downflow of the cleaned air is formed in the internal space 12 in the chamber 11. Further, a punching plate 14 perforated with a multitude of air outlets is provided right below the ceiling wall 11f to uniformly disperse the cleaned air supplied from the fan filter unit 13.

As shown in FIG. 3, in the substrate processing apparatus 1, a conveyance opening 11b1 is provided in the sidewall 11b facing the substrate conveyor robot 111 among the four sidewalls 11b to 11e, and the internal space 12 communicates with the outside of the chamber 11 therethrough. For this reason, a hand (not shown) of the substrate conveyor robot 111 can access the substrate processing part SP through the conveyance opening 11b1 . In other words, by providing the conveyance opening 11b1 , the substrate W can be loaded into or unloaded from the internal space 12. Further, a shutter 15 for opening and closing this conveyance opening 11b1 is attached to the sidewall 11b.

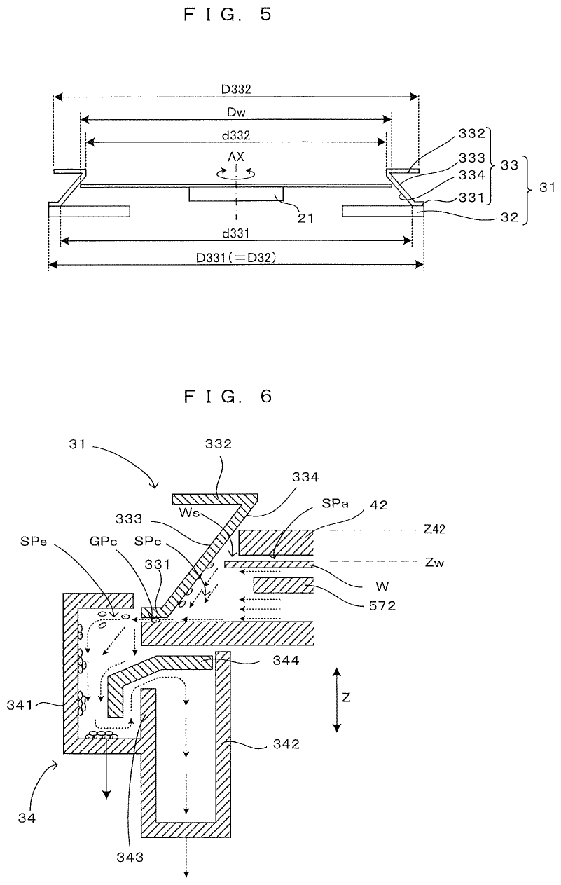

A shutter opening/closing mechanism (not shown) is connected to the shutter 15, and opens or closes the shutter 15 in response to an opening/closing command from the control unit 10. More specifically, in the substrate processing apparatus 1, the shutter opening/closing mechanism opens the shutter 15 in carrying an unprocessed substrate W into the chamber 11, and the unprocessed substrate W is carried in a face-up posture to the substrate processing part SP of the rotating mechanism 2 by a hand of a substrate conveyor robot 111. That is, the substrate W is placed on the spin chuck (denoted by 21 in FIG. 5) with an upper surface Wf facing up. If the hand of the substrate conveyor robot 111 is retracted from the chamber 11 after the substrate W is carried into, the shutter opening/closing mechanism closes the shutter 15. Then, a bevel processing is performed on the peripheral edge part Ws of the substrate W, as an example of a “substrate processing” of the invention by the substrate processing part SP, in the processing space (equivalent to a sealed space SPs to be described in detail later) of the chamber 11. Further, after the bevel processing is finished, the shutter opening/closing mechanism opens the shutter 15 again and the hand of the substrate conveyor robot 111 carries out the processed substrate W from the substrate processing part SP. As just described, in the present embodiment, the internal space 12 of the chamber 11 is kept in a room temperature atmosphere. Note that the “room temperature” means a temperature in a range of 5° C. to 35° C. in the present specification.

As shown in FIG. 3, the sidewall 11d is positioned on the opposite side of the sidewall 11b with respect to the substrate processing part SP (FIG. 2) installed on the base member 17. In this sidewall 11d, provided is a maintenance opening 11d1. During maintenance, as shown in this figure, the maintenance opening 11d1 is opened. For this reason, an operator can access the substrate processing part SP through the maintenance opening 11d1 from the outside of the apparatus. On the other hand, during the substrate processing, a lid member 19 is so attached as to close the maintenance opening 11d1. Thus, in the present embodiment, the lid member 19 is detachable from the sidewall 11d.

Further, on an outer surface of the sidewall 11e, a heated gas supplier 47 for supplying the substrate processing part SP with a heated inert gas (nitrogen gas in the present embodiment) is attached. This heated gas supplier 47 incorporates a heater 471.

Thus, on the outer wall side of the chamber 11, the shutter 15, the lid member 19, and the heated gas supplier 47 are arranged. On the other hand, in an inner side of the chamber 11, i.e., in the internal space 12, the substrate processing part SP is installed on the upper surface of the base member 17 having the raised floor structure.

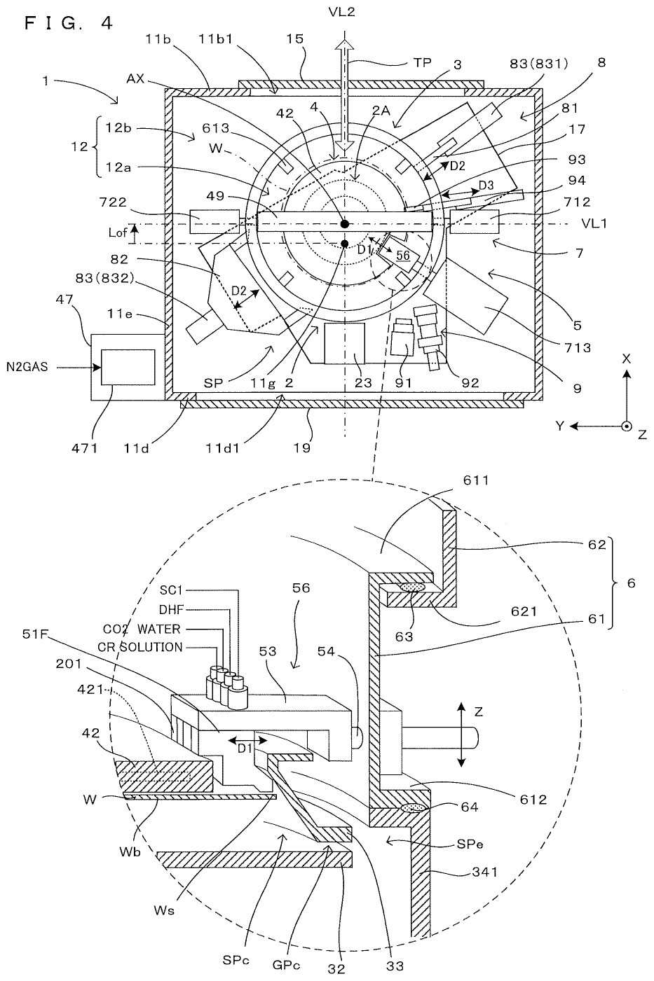

FIG. 4 is a plan view schematically showing the configuration of the substrate processing part installed on the base member. Hereinafter, for clarifying the arrangement relation and operation of the components of the apparatus, a coordinate system with a Z direction as a vertical direction and with an XY plane as a horizontal plane is shown as appropriate. In the coordinate system of FIG. 4, it is assumed that a horizontal direction in parallel to a conveyance path TP of the substrate W is an “X direction” and a horizontal direction orthogonal to the X direction is a “Y direction”. In more detail, directions from the internal space 12 of the chamber 11 toward the conveyance opening 11b1 and the maintenance opening 11d1 are referred to as a “+X direction” and a “−X direction”, respectively, directions from the internal space 12 of the chamber 11 toward the sidewalls 11c and 11e are referred to as a “−Y direction” and a “+Y direction”, respectively, and directions vertically upward and downward are referred to as a “+Z direction” and a “−Z direction”, respectively.

The substrate processing part SP includes a holding/rotating mechanism 2, a scattering preventing mechanism 3, an upper surface protecting/heating mechanism 4, a processing mechanism 5, an atmosphere separating mechanism 6, an elevating mechanism 7, a centering mechanism 8, and a substrate observing mechanism 9. These mechanisms are provided on the base member 17. Specifically, with reference to the base member 17 having rigidity higher than that of the chamber 11, the holding/rotating mechanism 2, the scattering preventing mechanism 3, the upper surface protecting/heating mechanism 4, the processing mechanism 5, the atmosphere separating mechanism 6, the elevating mechanism 7, the centering mechanism 8, and the substrate observing mechanism 9 are arranged to one another with a positional relation determined in advance.

The holding/rotating mechanism 2 includes a substrate holder 2A for holding the substrate W substantially in a horizontal posture with a surface of the substrate W facing up and a rotating mechanism 2B for synchronously rotating the substrate holder 2A holding the substrate W and part of the scattering preventing mechanism 3. For this reason, when the rotating mechanism 2B operates in response to a rotation command from the control unit 10, the substrate W and a rotating cup 31 of the scattering preventing mechanism 3 are rotated about an axis of rotation AX extending in parallel to the vertical direction Z.

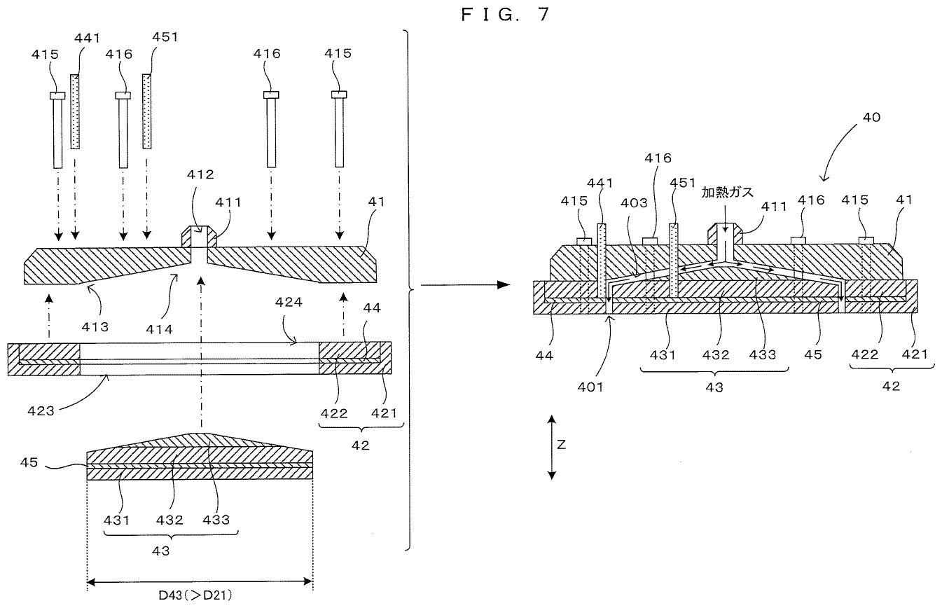

As shown in FIG. 2, the substrate holder 2A includes the spin chuck 21 which is a disk-like member smaller than the substrate W. The spin chuck 21 corresponds to one example of a “substrate holder” of the present invention and is made of resin. Further, in a horizontal plane (XY plane), an upper surface of the spin chuck 21 is substantially horizontal and narrower than a lower surface of a second under block of the upper surface protecting/heating mechanism 4 described later. As shown in FIG. 7 described later, a diameter D21 of the upper surface of the spin chuck 21 and a diameter D43 of the lower surface of the second under block have a relation of (D43>D21). Moreover, the upper surface of the spin chuck 21 is positioned vertically below the lower surface of the second under block. The spin chuck 21 is so provided that a center axis thereof coincides with the axis of rotation AX. Especially in the present embodiment, as shown in FIG. 4, a center of the substrate holder 2A (which corresponds to the center axis of the spin chuck 21) is offset in the (+X) direction relative to a center 11g of the chamber 11. Specifically, the substrate holder 2A is arranged so that the center axis (axis of rotation AX) of the spin chuck 21 may be positioned at a processing position deviated from the center 11g of the internal space 12 toward a side of the conveyance opening 11b1 by a distance Lof in a plan view of the chamber 11 viewed from above. Further, for clarifying the later-described arrangement relation of the components of the apparatus, in the present specification, a virtual line passing through the center (axis of rotation AX) of the substrate holder 2A which is offset and being orthogonal to the conveyance path TP and another virtual line in parallel to the conveyance path TP are referred to as a “first virtual horizontal line VL1”and a “second virtual horizontal line VL2”, respectively.

A cylindrical rotary shaft 22 is coupled to a lower surface of the spin chuck 21. The rotary shaft 22 extends in the vertical direction Z with an axis line thereof coinciding with the axis of rotation AX. Further, the rotating mechanism 2B is connected to the rotary shaft 22.

The rotating mechanism 2B has a motor 23 which generates a rotational driving force for rotating the substrate holder 2A and the rotating cup 31 of the scattering preventing mechanism 3 and a power transmitter 24 for transmitting the rotational driving force. The motor 23 has a rotation shaft 231 rotating with generation of the rotational driving force. The motor 23 is provided at a motor attachment portion 171 of the base member 17 in a posture with the rotation shaft 231 extending vertically downward.

At a tip part of the rotation shaft 231 protruding downward from the base member 17, attached is a first pulley 241. At a lower end part of the substrate holder 2A, attached is a second pulley 242. In more detail, the lower end part of the substrate holder 2A is inserted into the through hole provided in a spin chuck attachment portion 172 of the base member 17 and protrudes downward from the base member 17. This protruding portion is provided with the second pulley 242. Then, an endless belt 243 is put over between the first pulley 241 and the second pulley 242. Thus, in the present embodiment, the first pulley 241, the second pulley 242, and the endless belt 243 constitute the power transmitter 24.

A through hole (not shown) is provided at a central part of the spin chuck 21 and communicates with an internal space of the rotary shaft 22. A pump 26 is connected to the internal space via a pipe 25 having a valve (not shown) disposed therein. This pump 26 and the valve are electrically connected to the control unit 10 and operate in response to a command from the control unit 10. In this way, a negative pressure and a positive pressure are selectively applied to the spin chuck 21. When the pump 26 applies a negative pressure to the spin chuck 21, for example, with the substrate W placed substantially in a horizontal posture on the upper surface of the spin chuck 21, the spin chuck 21 sucks and holds the substrate W from below. On the other hand, if the pump 26 applies a positive pressure to the spin chuck 21, the substrate W can be taken out from the upper surface of the spin chuck 21. Further, if the suction of the pump 26 is stopped, the substrate W is horizontally movable on the upper surface of the spin chuck 21.

A nitrogen gas supplier 29 is connected to the spin chuck 21 through a pipe 28 provided in a central part of the rotary shaft 22. The nitrogen gas supplier 29 supplies a nitrogen gas at a room temperature supplied from a utility of a factory, in which the substrate processing system 100 is installed, to the spin chuck 21 at a flow rate and a timing corresponding to a nitrogen gas supply command from the control unit 10, and causes the nitrogen gas to flow from the central part to a radially outer side on the side of a lower surface Wb of the substrate W. Note that although the nitrogen gas is used in the present embodiment, another inert gas may be used. This point also applies to a heated gas discharged from a central nozzle to be described later. Further, the “flow rate” means a moving amount of a fluid such as the nitrogen gas per unit time.

The rotating mechanism 2B includes a power transmitter 27 (FIG. 2) for not only rotating the spin chuck 21 integrally with the substrate W, but also rotating the rotating cup 31 in synchronization with the former rotation. The power transmitter 27 includes an annular member 27a (FIG. 2) made of a non-magnetic material or resin, spin chuck side magnets (not shown) built-in the annular member 27a, and cup side magnets (not shown) built-in a lower cup 32, which is one component of the rotating cup 31. The annular member 27a is attached to the rotary shaft 22 and rotatable about the axis of rotation AX together with the rotary shaft 22. More particularly, the rotary shaft 22 includes a flange part 22a protruding radially outward at a position right below the spin chuck 21 as shown in FIG. 5. The annular member 27a is arranged concentrically with respect to the flange part 22a, and coupled and fixed with an unillustrated bolt or the like.

A plurality of spin chuck side magnets are arranged radially and at equal angular intervals (10° in the present embodiment) with the axis of rotation AX as a center on an outer peripheral edge part of the annular member 27a. In the present embodiment, an N-pole and an S-pole are respectively arranged on an outer side and an inner side of one of the two spin chuck side magnets adjacent to each other, and an S-pole and an N-pole are respectively arranged on an outer side and an inner side of the other magnet.

Similarly to these spin chuck side magnets, a plurality of cup side magnets are arranged radially and at equal angular intervals with the axis of rotation AX as a center. These cup side magnets are built in the lower cup 32. The lower cup 32 is a constituent component of the scattering preventing mechanism 3 to be described next and, as shown in FIGS. 4 and 5, has an annular shape. That is, the lower cup 32 has an inner peripheral surface capable of facing the outer peripheral surface of the annular member 27a. An inner diameter of this inner peripheral surface is larger than an outer diameter of the annular member 27a. The lower cup 32 is arranged concentrically with the rotary shaft 22 and the annular member 27a while this inner peripheral surface is separated from the outer peripheral surface of the annular member 27a by a predetermined distance (=(the inner diameter-the outer diameter)/2) and facing the outer peripheral surface of the annular member 27a. Engaging pins 35 and coupling magnets 36 are provided on the upper surface of the outer peripheral edge of the lower cup 32, the upper cup 33 is coupled to the lower cup 32 by these, and this coupled body functions as the rotating cup 31.

The lower cup 32 is supported rotatably about the axis of rotation AX on the upper surface of the base member 17 while being kept in the above arranged state by a bearing not shown in figures. The plurality of cup side magnets are arranged radially and at equal angular intervals with the axis of rotation AX as a center on an inner peripheral edge part of this lower cup 32. Further, two cup side magnets adjacent to each other are arranged similarly to the spin chuck side magnets. That is, an N-pole and an S-pole are respectively arranged on an outer side and an inner side of one magnet, and an S-pole and an N-pole are respectively arranged on an outer side and an inner side of the other magnet.

In the power transmitter 27 thus configured, if the annular member 27a is rotated together with the rotary shaft 22 by the motor 23, the lower cup 32 rotates in the same direction as the annular member 27a while maintaining an air gap GPa (gap between the annular member 27a and the lower cup 32) by the action of magnetic forces between the spin chuck side magnets and the cup side magnets. In this way, the rotating cup 31 rotates about the axis of rotation AX. That is, the rotating cup 31 rotates in the same direction as and in synchronization with the substrate W.

The scattering preventing mechanism 3 includes the rotating cup 31 rotatable about the axis of rotation AX while surrounding the outer periphery of the substrate W held on the spin chuck 21 and a fixed cup 34 fixedly provided to surround the rotating cup 31. The rotating cup 31 is provided rotatably about the axis of rotation AX while surrounding the outer periphery of the rotating substrate W by the upper cup 33 being coupled to the lower cup 32.

FIG. 5 is a diagram showing a dimensional relationship between the substrate held on the spin chuck and the rotating cup. FIG. 6 is a diagram partially showing the rotating cup and the fixed cup. The lower cup 32 has an annular shape. The lower cup 32 has an outer diameter larger than that of the substrate W and is arranged rotatably about the axis of rotation AX while radially protruding from the substrate W held on the spin chuck 21 in a plan view vertically from above. In this protruding region, i.e. an upper surface peripheral edge part of the lower cup 32, the engaging pins (not shown) standing vertically upward along a circumferential direction and the flat plate-like lower magnets (not shown) are alternately mounted.

On the other hand, as shown in FIGS. 2, 3, and 5, the upper cup 33 includes a lower annular part 331, an upper annular part 332 and an inclined part 333 coupling these. An outer diameter D331 of the lower annular part 331 is equal to an outer diameter D32 of the lower cup 32 and the lower annular part 331 is located vertically above the peripheral edge part 321 of the lower cup 32. Recesses open downward are provided to be fittable to tip parts of the engaging pins in regions vertically above the engaging pins on the lower surface of the lower annular part 331. Further, upper magnets are mounted in regions vertically above the lower magnets. Thus, the upper cup 33 is engageable with and disengageable from the lower cup 32 with the recesses and the upper magnets facing the engaging pins and the lower magnets, respectively.

The upper cup 33 is movable up and down along the vertical direction by the elevating mechanism 7. If the upper cup 33 is moved up by the elevating mechanism 7, a conveyance space for carrying in and out the substrate W is formed between the upper cup 33 and the lower cup 32 in the vertical direction. On the other hand, if the upper cup 33 is moved down by the elevating mechanism 7, the recesses 335 are fit to cover the tip parts of the engaging pins 35 and the upper cup 33 is positioned in a horizontal direction with respect to the lower cup 32. Further, the upper magnets 37 approach the lower magnets 36, and the positioned upper and lower cups 33, 32 are bonded to each other by attraction forces generated between the both magnets. In this way, as shown in a partial enlarged view of FIG. 4 and FIG. 6, the upper and lower cups 33, 32 are integrated in the vertical direction with a gap GPc extending in the horizontal direction formed. The rotating cup 31 is rotatable about the axis of rotation AX while forming the gap GPc.

In the rotating cup 31, as shown in FIG. 5, an outer diameter D332 of the upper annular part 332 is slightly smaller than the outer diameter D331 of the lower annular part 331 as shown in FIG. 7. Further, if diameters d331, d332 of the inner peripheral surfaces of the lower and upper annular parts 331, 332 are compared, the lower annular part 331 is larger than the upper annular part 332 and the inner peripheral surface of the upper annular part 332 is located inside the inner peripheral surface of the lower annular part 331 in a plan view vertically from above. The inner peripheral surface of the upper annular part 332 and that of the lower annular part 331 are coupled by the inclined part 333 over the entire circumference of the upper cup 33. Thus, the inner peripheral surface of the inclined part 333, i.e. a surface surrounding the substrate W, serves as an inclined surface 334. Specifically, as shown in FIG. 6, the inclined part 333 can collect liquid droplets scattered from the substrate W by surrounding the outer periphery of the rotating substrate W, and a space surrounded by the upper and lower cups 33, 32 functions as a collection space SPc.

Moreover, the inclined part 333 facing the collection space SPc is inclined upwardly of the peripheral edge part of the substrate W from the lower annular part 331. For this reason, as shown in FIG. 6, the liquid droplets collected by the inclined part 333 can flow to a lower end part of the upper cup 33, i.e. the lower annular part 331, along the inclined surface 334, and can be discharged to the outside of the rotating cup 31 via the gap GPc.

The fixed cup 34 is provided to surround the rotating cup 31 and forms a discharge space SPe. The fixed cup 34 includes a liquid receiving part 341 and an exhaust part 342 provided inside the liquid receiving part 341. The liquid receiving part 341 has a cup structure open to face an opening (left opening of FIG. 6) of the gap GPc on a side opposite to the substrate. That is, an internal space of the liquid receiving part 341 functions as the discharge space SPe and communicates with the collection space SPc via the gap GPc. Therefore, the liquid droplets collected by the rotating cup 31 are guided into the discharge space SPe via the gap GPc together with gas components. Then, the liquid droplets are collected in a bottom part of the liquid receiving part 341 and discharged from the fixed cup 34.

On the other hand, the gas components are collected into the exhaust part 342. This exhaust part 342 is partitioned from the liquid receiving part 341 via a partition wall 343. Further, a gas guiding part 344 is arranged above the partition wall 343. The gas guiding part 344 extends from a position right above the partition wall 343 into the discharge space SPe and the exhaust part 342, thereby forming a flow passage for gas components having a labyrinth structure by covering the partition wall 343 from above. Accordingly, the gas components, out of a fluid flowing into the liquid receiving part 341, are collected in the exhaust part 342 by way of the flow passage. This exhaust part 342 is connected to an exhaust part 38. Thus, a pressure in the fixed cup 34 is adjusted by the operation of the exhaust part 38 in response to a command from the control unit 10, and the gas components in the exhaust part 342 are efficiently exhausted. Further, a pressure and a flow rate in the discharge space SPe are adjusted by a precise control of the exhaust part 38. For example, the pressure in the discharge space SPe is reduced to below that in the collection space SPc. As a result, the liquid droplets in the collection space SPc can be efficiently drawn into the discharge space SPe and movements of the liquid droplets from the collection space SPc can be promoted.

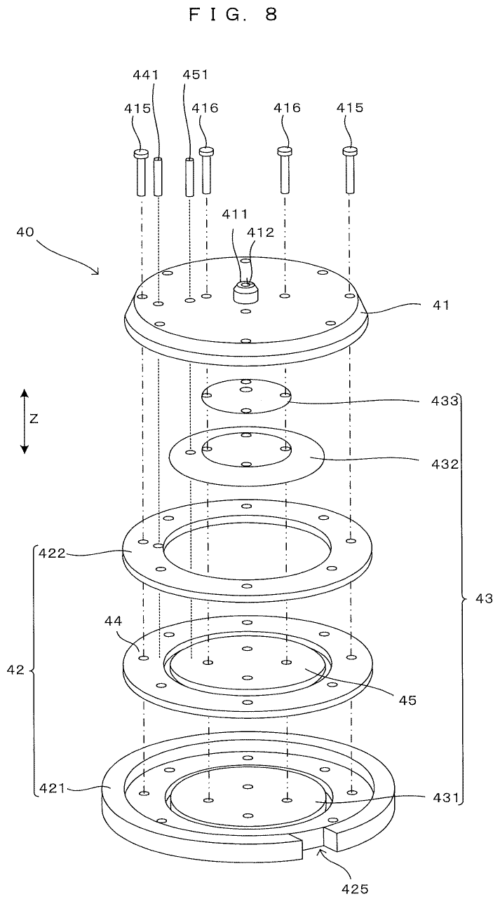

FIG. 7 is a cross-sectional view showing a configuration of the upper surface protecting/heating mechanism. FIG. 8 is an exploded view of the upper surface protecting/heating mechanism shown in FIG. 7. The upper surface protecting/heating mechanism 4 is arranged above the upper surface Wf of the substrate W held on the spin chuck 21. In more detail, the upper surface protecting/heating mechanism 4 has a base block 41, a first under block 42 and a second under block 43 which are arranged vertically below the base block 41, a peripheral edge heater 44 arranged inside the first under block 42, and a central heater 45 arranged inside the second under block 43. The base block 41, the first under block 42, the second under block 43, the peripheral edge heater 44, and the central heater 45 have respective configurations described below and are combined to form a shielding plate structure 40.

As shown in FIG. 8, the base block 41 has a substantially disk-like shape as a whole. To an upper surface central part of the base block 41, attached is an input port 411 for feeding a nitrogen gas to be supplied to the upper surface Wf of the substrate W. As shown in FIG. 2, the heated gas supplier 47 is connected to the input port 411 through a pipe 46. The heated gas supplier 47 uses the heater 471 to heat a nitrogen gas at room temperature supplied from utilities of the factory in which the substrate processing system 100 is installed, and feeds the nitrogen gas to the base block 41 at a flow rate and a timing in accordance with the nitrogen gas supply command from the control unit 10.

In the base block 41, as shown in FIG. 7, an upper end part of the input port 411 is opened, and this opening 412 corresponds to one example of a “first opening” of the present invention. Further, an opening 413 which is wider than the opening 412 is provided at a central part of a lower surface of the base block 41. This opening 413 corresponds to one example of a “second opening” of the present invention. Then, on the side of the lower surface of the base block 41, formed is a funnel-like space 414. This funnel-like space 414 has an inner diameter which becomes larger as it goes downward from the opening 412 and is connected to the opening 413.

As shown in FIGS. 7 and 8, the first under block 42 has an annular member 421 with a flange and an annular member 422. Further, the peripheral edge heater 44 having an annular shape is sandwiched by the annular member 421 and the annular member 422 and incorporated in the first under block 42. The annular member 421 has a diameter which is slightly shorter than that of the substrate W. Further, as shown in FIG. 8, a cut 425 is provided at a peripheral edge part of the first under block 42. This is provided in order to prevent interference with the processing liquid discharge nozzle included in the processing mechanism 5. The cut 425 is opened radially outward.

In the annular member 421, at the central part in a region surrounded by the flange portion, a through hole having the same shape as the opening 413 is provided and the central part has a hollow shape. Further, like the central part of the annular member 421, the annular member 422 and the peripheral edge heater 44 also each have an annular shape provided with a through hole having the same shape as the opening 413. Then, the peripheral edge heater 44 and the annular member 422 are layered in this order on an upper surface of the annular member 421 while the above-described respective through holes are caused to coincide with each other. In a layered body having such a structure (=the first under block 42+the peripheral edge heater 44), the peripheral edge heater 44 having an annular shape is sandwiched by the annular member 421 and the annular member 422 and incorporated in the first under block 42. Further, as shown in the left figure in FIG. 7, a through hole 423 is formed in a central part of the layered body, and a space inside the through hole 423 corresponds to one example of a “penetration space” of the present invention. Furthermore, an opening 424 on an upper side of this through hole 423 corresponds to a “third opening” of the present invention. Then, the above-described layered body is in close contact with the base block 41 and the first under block 42 and the peripheral edge heater 44 are fixed to the base block 41 with a fastening member 415 such as a bolt or the like so that the opening 424 may coincide with the opening 413 of the base block 41 and an upper surface of the first under block 42 may coincide with a lower surface of the base block 41. Then, the funnel-like space 414 gets connected to the above-described penetration space and these spaces become unified. By this connection, formed is a space (=the funnel-like space 414+the penetration space) in which the second under block 43 described next can be loosely inserted.

The second under block 43 has a disk member 431, an intermediate member 432, and a truncated cone member 433. The disk member 431 has an outer diameter which is slightly smaller than an inner diameter of the through hole 423 and has the same thickness as the annular member 421, in other words, has the same height in the vertical direction. The intermediate member 432 has a disk portion having the same shape as the disk member 431 and a truncated cone portion extended vertically upward from the disk portion. Then, the central heater 45 is sandwiched by the disk member 431 and the intermediate member 432, to be thereby incorporated in the second under block 43. Further, the central heater 45 has the same shape as the disk member 431 and has the same thickness as the central heater 45. The central heater 45, the intermediate member 432, and the truncated cone member 433 are layered in this order on an upper surface of the disk member 431 while respective rotational symmetry axes of the disk member 431, the central heater 45, the intermediate member 432, and the truncated cone member 433 are caused to coincide with one another. The layered body which is thus formed (=the second under block 43+the central heater 45) is inserted into a space formed by the funnel-like space 414 and the penetration space so that a lower surface (i.e., the lower surface of the disk member 431) of the layered body may be caused to coincide with a lower surface of the first under block 42 in the vertical direction. Then, while this insertion state is maintained, the second under block 43 and the central heater 45 are fixed to the base block 41 with a fastening member 416 such as a bolt or the like. In the shielding plate structure 40, a clearance region 403 is formed as a gas supply path between the base block 41 and the first under block 42 and the second under block 43. Further, an annular air outlet 401 is formed between the lower surface of the first under block 42 and the lower surface of the second under block 43. As a result, when the heated gas is fed to the upper surface protecting/heating mechanism 4 through the opening 412, the heated gas is guided to the annular air outlet 401 through the clearance region 403. Then, the heated gas is supplied uniformly from the annular air outlet 401 to the vicinity of the peripheral edge part of the upper surface Wf of the substrate W.

Further, in the upper surface protecting/heating mechanism 4, a power supply member 441 is provided to drive the peripheral edge heater 44. As shown in FIG. 7, the power supply member 441 is inserted into a through hole (not shown) provided in the base block 41 and the annular member 422 and connected to the peripheral edge heater 44. For this reason, when electric power for activating the peripheral edge heater 44 is given from the heater driver 402 through the power supply member 441 to the peripheral edge heater 44, heat is released from the peripheral edge heater 44. This heat is given to the peripheral edge part Ws of the substrate W through the annular member 421 and heats the heated gas flowing toward the annular air outlet 401 in the clearance region 403. The peripheral edge part Ws of the substrate W is thereby warmed, to thereby increase the temperature at the peripheral edge part.

In order to drive the central heater 45 besides the peripheral edge heater 44, a power supply member 451 is provided. As shown in FIG. 7, the power supply member 451 is inserted into the through holes provided in the base block 41, the truncated cone member 433, and the intermediate member 432 and connected to the central heater 45. For this reason, when electric power for activating the central heater 45 is given from the heater driver 402 through the power supply member 451 to the central heater 45, heat is released from the central heater 45. This heat is given to the central part of the upper surface Wf of the substrate W through the annular member 421 and heats the heated gas flowing toward the annular air outlet 401 in the clearance region 403. The temperature of the heated gas to be supplied to the vicinity of the peripheral edge part of the substrate W is thereby increased, to thereby raise the temperature at the peripheral edge part of the substrate W. Further, the central part of the upper surface Wf of the substrate W is warmed through the disk member 431 and the temperature difference from that at the peripheral edge part Ws can be reduced. In other words, the inplane temperature of the substrate W can be uniformized. It is thereby possible to suppress warp of the substrate W and stabilize a liquid-reaching position of the processing liquid. Further, in the present embodiment, as shown in FIG. 7, a relation of (D43>D21) is satisfied between the spin chuck 21 made of resin and the second under block. Specifically, in a horizontal plane, the upper surface of the spin chuck 21 is narrower than the lower surface of the second under block 43 and positioned vertically below the lower surface of the second under block 43. Therefore, the spin chuck 21 is less susceptible to the heated gas supplied from the annular air outlet 401 to the vicinity of the peripheral edge part and the heat from the peripheral edge heater 44, and it is therefore possible to prevent degradation, shape change, or the like of the spin chuck 21 and stabilize the bevel processing.

Further, the heater driver 402 can switch among the power supply to the peripheral edge heater 44 and the central heater 45, the power supply only to the peripheral edge heater 44, and stop of the power supply to both heaters. Moreover, in a case where power is supplied to both the peripheral edge heater 44 and the central heater 45, the amount of power to be supplied to the peripheral edge heater 44 and the amount of power to be supplied to the central heater 45 can be individually controlled. With this power control, the amount of heat generation of the peripheral edge heater 44 and the amount of heat generation of the central heater 45 can be adjusted independently of each other. As a result, in the present embodiment, it is possible to finely control the temperature of the substrate W. In particular, it is preferable to make control so that the amount of heat generation of the peripheral edge heater 44 should be higher than the amount of heat generation of the central heater 45.

Herein, when the heater 471 is disposed in the internal space 12 of the chamber 11, there is a possibility that the heat radiated from the heater 471 may adversely affect the substrate processing part SP, in particular, the processing mechanism 5 and the substrate observing mechanism 9. Then, in the present embodiment, the heated gas supplier 47 having the heater 471 is disposed outside the chamber 11 as shown in FIG. 4. Further, in the present embodiment, a ribbon heater 48 is mounted in a part of the pipe 46. The ribbon heater 48 generates heat in response to a heating command from the control unit 10 to heat the nitrogen gas flowing in the pipe 46.

The nitrogen gas which is heated thus, i.e., the heated gas has not only the function of heating the peripheral edge part Ws of the substrate W as described above but also a function of suppressing the atmosphere around the substrate W from entering onto the upper surface Wf of the substrate W. In other words, it is possible to effectively prevent liquid droplets contained in the above-described atmosphere from being swallowed into the space SPa sandwiched between the substrate W and the shielding plate structure 40.

As shown in FIG. 2, the shielding plate structure 40 which is configured as described above is supported by the support member 404. An upper end part of the support member 404 is fixed to a beam member 49 extending along the first virtual horizontal line VL1. This beam member 49 is connected to the elevating mechanism 7 installed on the upper surface of the base member 17 and moved up and down by the elevating mechanism 7 in response to a command from the control unit 10. For example, in FIG. 2, the beam member 49 is positioned below, whereby the shielding plate structure 40 (FIG. 7) coupled to the beam member 49 is located at the processing position through the support member 404. On the other hand, when the elevating mechanism 7 moves up the beam member 49 in response to a move-up command from the control unit 10, the beam member 49, the support member 404, and the shielding plate structure 40 integrally move upward and the upper cup 33 is also linked, separated from the lower cup 32 and moves up. The upper cup 33 and the shielding plate structure 40 thereby become spaced wider apart from the spin chuck 21 and the substrate W can be carried to and from the spin chuck 21.

The processing mechanism 5 includes processing liquid discharge nozzles 51F (see FIG. 4) arranged on the upper surface side of the substrate W, processing liquid discharge nozzles 51B (see FIG. 2) arranged on the lower surface side of the substrate W and processing liquid suppliers 52 for supplying the processing liquid to the processing liquid discharge nozzles 51F, 51B. The processing liquid discharge nozzles 51F on the upper surface side and the processing liquid discharge nozzles 51B on the lower surface side are referred to as “upper surface nozzles 51F” and “lower surface nozzles 51B”, respectively, to be distinguished. Further, two processing liquid suppliers 52 shown in FIG. 2 are identical.

In the present embodiment, three upper surface nozzles 51F are provided, and the processing liquid supplier 52 is connected thereto. Further, the processing liquid supplier 52 is configured to be capable of supplying chemical liquids such as SC1 and DHF and functional water (CO₂ water or the like) as the processing liquids, and the SC1, DHF and functional water can be independently discharged from the three upper surface nozzles 51F, respectively.

Each of the upper surface nozzles 51F is provided with a discharge port (not shown) for discharging the processing liquid in a lower surface of a tip thereof. Then, as shown in an enlarged view in FIG. 4, with the respective discharge ports facing the peripheral edge part of the upper surface Wf of the substrate W, lower parts of a plurality of (three in the present embodiment) upper surface nozzles 51F are arranged in the cut 425 (see FIG. 8) of the first under block 42 and upper parts of the upper surface nozzles 51F are mounted movably to a nozzle holder 53 in a radial direction D1 (in a direction inclined with respect to the first virtual horizontal line VL1 with a nozzle discharge elevation angle of about 45° and a turning angle of about 65°). This nozzle holder 53 is connected to a nozzle mover 54.

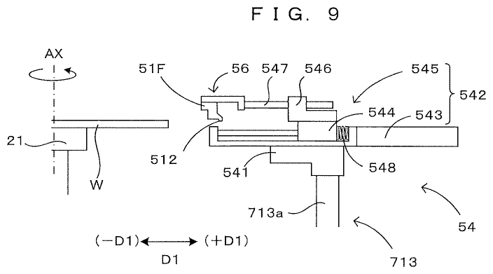

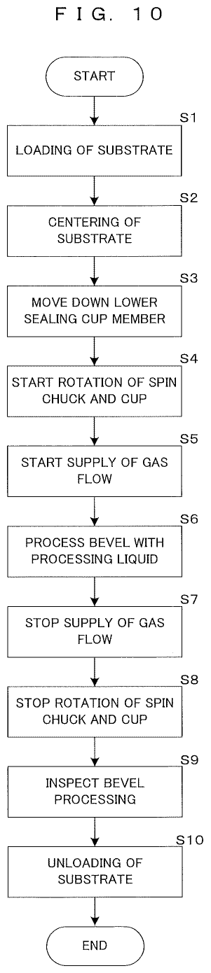

FIG. 9 is a diagram schematically showing a configuration of the nozzle mover. As shown in FIG. 9, the nozzle mover 54 is attached to an upper end part of a lifter 713a of an elevator 713 described later while holding the nozzle head 56 (=the upper surface nozzle 51F+the nozzle holder 53). For this reason, in response to an up-and-down command from the control unit 10, the lifter 713a expands and contracts in the vertical direction and accordingly the nozzle mover 54 and the nozzle head 56 move in the vertical direction Z.

Further, in the nozzle mover 54, a base member 541 is fixed to the upper end part of the lifter 713a. To this base member 541, attached is a linear actuator 542. The linear actuator 542 has a motor (hereinafter, referred to as a “nozzle drive motor”) 543 serving as a drive source of nozzle movement in the radial direction X and a motion conversion mechanism 545 for converting a rotational motion of a rotating body such as a ball screw or the like coupled to an axis of rotation of the nozzle drive motor 543 into a linear motion to thereby cause a slider 544 to reciprocally move in the radial direction D1. Further, in the motion conversion mechanism 545, in order to stabilize the movement of the slider 544 in the radial direction D1, a guide such as an LM guide (registered trademark) or the like is used.

To the slider 544 driven reciprocally in the radial direction X, a head support member 547 is coupled with a coupling member 546 interposed therebetween. This head support member 547 has a bar shape extending in the radial direction X. An end part of the head support member 547 in the (+D1) direction is fixed to the slider 544. On the other hand, an end part of the head support member 547 in the (−D1) direction is horizontally extended toward the spin chuck 21, and the nozzle head 56 is attached to a tip part thereof. For this reason, when the nozzle drive motor 543 is rotated in response to a nozzle moving command from the control unit 10, the slider 544, the head support member 547, and the nozzle head 56 are integrally moved in the (+D1) direction or the (−D1) direction in accordance with a rotation direction thereof by a distance corresponding to the amount of rotation. As a result, the upper surface nozzle 51F attached to the nozzle head 56 is positioned in the radial direction D1. As shown in FIG. 9, for example, when the upper surface nozzle 51F is positioned at a home position which is set in advance, a spring member 548 provided in the motion conversion mechanism 545 is compressed by the slider 544, to thereby give an urging force to the slider 544 in the (−X) direction. It is thereby possible to control backlash included in the motion conversion mechanism 545. Specifically, since the motion conversion mechanism 545 has mechanical components such as a guide or the like, it is practically difficult to make the backlash along the radial direction DI zero, and the positioning accuracy of the upper surface nozzle 51F in the radial direction DI is reduced if not sufficient consideration is made thereon. Then, in the present embodiment, by providing the spring member 548, when the upper surface nozzle 51F is immobilized at the home position, the backlash is always one-sided toward the (−D1) direction. This produces the following effects. In response to the nozzle moving command from the control unit 10, the nozzle mover 54 collectively drives the three upper surface nozzles 51F toward the direction D1. This nozzle moving command includes information on a nozzle moving distance. When the upper surface nozzle 51F is moved by the nozzle moving distance specified in the radial direction D1 on the basis of this information, the upper surface nozzle 51F is accurately positioned at a bevel processing position.

The discharge ports (not shown) of the upper surface nozzle 51F positioned at the bevel processing position are facing the peripheral edge part of the upper surface Wf of the substrate W. When the processing liquid supplier 52 supplies the processing liquid corresponding to a supply command, out of three kinds of processing liquids, to the upper surface nozzle 51F for the processing liquid in response to the supply command from the control unit 10, the processing liquid is supplied from the upper surface nozzle 51F to a position set in advance from an end surface of the substrate W.

Further, to part of the constituent components of the nozzle mover 54, a lower sealing cup member 61 of the atmosphere separating mechanism 6 is detachably fixed. Specifically, when the bevel processing is performed, the upper surface nozzle 51F and the nozzle holder 53 are integrated with the lower sealing cup member 61 with the nozzle mover 54 interposed therebetween and moved up and down in the vertical direction Z together with the lower sealing cup member 61 by the elevating mechanism 7. On the other hand, when calibration processing is performed, the lower sealing cup member 61 is detached, and the upper surface nozzle 51F and the nozzle holder 53 are reciprocally moved in the radial direction D1 by the nozzle mover 54 and also moved up and down in the vertical direction Z by the elevating mechanism 7.

In the present embodiment, the lower surface nozzles 51B and a nozzle support 57 are provided below the substrate W held on the spin chuck 21 to discharge the processing liquid toward the peripheral edge part of the lower surface Wb of the substrate W. The nozzle support 57 has a thin cylindrical part 571 extending in the vertical direction and a flange part 572 having an annular shape and bent to expand radially outward in an upper end part of the cylindrical part 571. The cylindrical part 571 is shaped to be loosely insertable into an air gap formed between the annular member 27a and the lower cup 32. Then, as shown in FIG. 2, the nozzle support 57 is so fixedly arranged that the cylindrical part 571 is loosely inserted in the air gap and the flange part 572 is located between the substrate W held on the spin chuck 21 and the lower cup 32. Three lower surface nozzles 51B are mounted on a peripheral edge part of the upper surface of the flange part 572. Each lower surface nozzle 51B has a discharge port (not shown) open toward the peripheral edge part of the lower surface Wb of the substrate W and can discharge the processing liquid supplied from the processing liquid supplier 52 through a pipe 58.

The bevel processing is performed on the peripheral edge part of the substrate W with the processing liquids discharged from these upper surface nozzles 51F and lower surface nozzles 51B. Further, on the lower surface side of the substrate W, the flange part 572 is extended to the vicinity of the peripheral edge part Ws. For this reason, the nitrogen gas supplied to the lower surface side through the pipe 28 flows into the collection space SPc along the flange part 572. As a result, a backflow of the liquid droplets from the collection space SPc to the substrate W is effectively suppressed.

The atmosphere separating mechanism 6 has the lower sealing cup member 61 and an upper sealing cup member 62. Both of the upper and lower sealing cup members 61, 62 each have a tube shape open in the vertical direction. Then, inner diameters of those sealing cup members are larger than an outer diameter of the rotating cup 31, and the atmosphere separating mechanism 6 is arranged to completely surround the spin chuck 21, the substrate W held on the spin chuck 21, the rotating cup 31 and the upper surface protecting/heating mechanism 4 from above. In more detail, as shown in FIG. 2, the upper sealing cup member 62 is fixedly arranged at a position immediately below the punching plate 14 such that the upper opening thereof covers the opening 11f1 of the ceiling wall 11f from below. For this reason, a downflow of clean air fed into the chamber 11 is separated into a flow passing through the inside of the upper sealing cup member 62 and a flow passing outside the upper sealing cup member 62.

Further, a lower end part of the upper sealing cup member 62 has a flange part 621 bent inwardly and having an annular shape. An O-ring 63 is mounted on the upper surface of this flange part 621. The lower sealing cup member 61 is arranged movably in the vertical direction inside the upper sealing cup member 62.

An upper end part of the lower sealing cup member 61 has a flange part 611 bent to expand outward and having an annular shape. This flange part 611 overlaps the flange part 621 in a plan view vertically from above. For this reason, when the lower sealing cup member 61 moves down, as shown in the partial enlarged view of FIG. 4, the flange part 611 of the lower sealing cup member 61 is locked by the flange part 621 of the upper sealing cup member 62 through the O-ring 63. The lower sealing cup member 61 is thereby positioned at a lower limit position. At this lower limit position, the upper and lower sealing cup members 62, 61 are connected to each other in the vertical direction, and a downflow introduced into the upper sealing cup member 62 is guided toward the substrate W held on the spin chuck 21.

A lower end part of the lower sealing cup member 61 has a flange part 612 bent outwardly and having an annular shape. This flange part 612 overlaps an upper end part of the fixed cup 34 (upper end part of the liquid receiving part 341) in a plan view vertically from above. Therefore, at the lower limit position, the flange part 612 of the lower sealing cup member 61 is locked by the fixed cup 34 through an O-ring 64, as shown in the partial enlarged view of FIG. 4. The lower sealing cup member 61 and the fixed cup 34 are thereby connected to each other in the vertical direction, and a sealed space 12a is formed by the upper sealing cup member 62, the lower sealing cup member 61 and the fixed cup 34. The bevel processing on the substrate W can be performed inside this sealed space 12a. Specifically, by positioning the lower sealing cup member 61 at the lower limit position, the sealed space 12a is separated from an outside space 12b of the sealed space 12a (atmosphere separation). Therefore, the bevel processing can be stably performed without being influenced by an outside atmosphere. Further, the processing liquids are used to perform the bevel processing, and it is possible to reliably prevent the processing liquids from leaking from the sealed space 12a to the outside space 12b. Hence, the degree of freedom in selecting/designing components to be arranged in the outside space 12b is increased.

The lower sealing cup member 61 is also configured to be movable vertically upward. Further, the nozzle head 56 (=upper surface nozzles 51F+nozzle holder 53) is fixed to an intermediate part of the lower sealing cup member 61 in the vertical direction through the head support member 547 of the nozzle mover 54 as described above. Furthermore, besides this, as shown in FIGS. 2 and 4, the upper surface protecting/heating mechanism 4 is fixed to the intermediate part of the lower sealing cup member 61 through the beam member 49. Specifically, as shown in FIG. 4, the lower sealing cup member 61 is connected to one end part of the beam member 49, the other end part of the beam member 49, and the head support member 547 at three positions, respectively, different from one another in the circumferential direction. Then, when the elevating mechanism 7 moves up and down the one end part of the beam member 49, the other end part of the beam member 49, and the head support member 547, the lower sealing cup member 61 is also moved up and down accordingly.

As shown in FIGS. 2 and 4, a plurality of (four) projections 613 are provided to project inward as engaging parts engageable with the upper cup 33 on the inner peripheral surface of this lower sealing cup member 61. Each projection 613 is extended to a space below the upper annular part 332 of the upper cup 33. Further, each projection 613 is so mounted to be separated downward from the upper annular part 332 of the upper cup 33 with the lower sealing cup member 61 positioned at the lower limit position. Then, when the lower sealing cup member 61 moves upward, each projection 613 becomes engageable with the upper annular part 332 from below. Also after this engagement, when the lower sealing cup member 61 further moves upward, the upper cup 33 can be separated from the lower cup 32.

In the present embodiment, after the lower sealing cup member 61 is started to move up together with the upper surface protecting/heating mechanism 4 and the nozzle head 56 by the elevating mechanism 7, the upper cup 33 also moves up. The upper cup 33, the upper surface protecting/heating mechanism 4, and the nozzle head 56 are thereby separated upward from the spin chuck 21. When the lower sealing cup member 61 moves to a retracted position, formed is a conveyance space for allowing the hand of the substrate conveyor robot 111 to access the spin chuck 21. Then, the substrate W can be loaded onto the spin chuck 21 and unloaded from the spin chuck 21 through this conveyance space. Thus, in the present embodiment, the substrate W can access the spin chuck 21 with a minimum upward movement of the lower sealing cup member 61 by the elevating mechanism 7.

The elevating mechanism 7 has two elevation drivers 71, 72. In the elevation driver 71, a first elevation motor (not shown) is attached to a first elevation mounting portion 173 (FIG. 3) of the base member 17. The first elevation motor generates a rotational force by operating in response to a drive command from the control unit 10. Two elevators 712, 713 are coupled to this first elevation motor. The elevators 712, 713 simultaneously receive the above-described rotational force from the first elevation motor. Then, the elevator 712 moves up and down a support member 491 supporting the one end part of the beam member 49 along the vertical direction Z in accordance with the amount of rotation of the first elevation motor. Further, the elevator 713 moves up and down the head support member 547 supporting the nozzle head 56 along the vertical direction Z in accordance with the amount of rotation of the first elevation motor.

In the elevation driver 72, a second elevation motor (not shown) is attached to a second elevation mounting portion 174 (FIG. 3) of the base member 17. An elevator 722 is coupled to the second elevation motor. The second elevation motor generates a rotational force by operating in response to a drive command from the control unit 10 and gives the generated rotational force to the elevator 722. The elevator 722 moves up and down a support member 492 supporting the other end part of the beam member 49 along the vertical direction in accordance with the amount of rotation of the second elevation motor.

The elevation drivers 71, 72 synchronously and vertically move the support members 491, 492 and 54 fixed to the side surface of the lower sealing cup member 61 at three positions, respectively, different from one another in the circumferential direction. Therefore, the upper surface protecting/heating mechanism 4, the nozzle head 56, and the lower sealing cup member 61 can be stably moved up and down. Further, the upper cup 33 can be also stably moved up and down as the lower sealing cup member 61 is moved up and down.

The centering mechanism 8 performs centering processing while the suction by the pump 26 is stopped (i.e. while the substrate W is horizontally movable on the upper surface of the spin chuck 21). By this centering processing, the eccentricity of the substrate W with respect to the axis of rotation AX is cancelled and a center of the substrate W coincides with the axis of rotation AX. As shown in FIG. 4, the centering mechanism 8 has a single contact part 81 disposed on a side of the conveyance opening 11b1 with respect to the axis of rotation AX in a contact movement direction D2 inclined at about 40° with respect to the first virtual horizontal line VL1, a multi-contact part 82 disposed on a side of the maintenance opening 11d1, and a centering driver 83 for moving the single contact part 81 and the multi-contact part 82 in the contact movement direction D2.

The single contact part 81 has a shape extending in parallel to the contact movement direction D2 and is finished to be contactable with the end surface of the substrate W on the spin chuck 21 at a tip part on the side of the spin chuck 21. On the other hand, the multi-contact part 82 has a substantial Y shape in a plan view vertically from above and is finished to be contactable with the end surface of the substrate W on the spin chuck 21 at each tip part of a bifurcated portion on the side of the spin chuck 21. The single contact part 81 and the multi-contact part 82 are movable in the contact movement direction D2.

The centering driver 83 has a single mover 831 for moving the single contact part 81 in the contact movement direction D2 and a multi-mover 832 for moving the multi-contact part 82 in the contact movement direction D2. The single mover 831 is mounted on a single moving attachment portion 175 (FIG. 3) of the base member 17 and the multi-mover 832 is mounted on a multi-moving attachment portion 176 (FIG. 3) of the base member 17. While the centering processing of the substrate W is not performed, as shown in FIG. 4, the centering driver 83 positions the single contact part 81 and the multi-contact part 82 away from the spin chuck 21. For this reason, the single contact part 81 and the multi-contact part 82 are away from the conveyance path TP, and it is thereby possible to effectively prevent interference of the single contact part 81 and the multi-contact part 82 with the substrate W loaded into or unloaded from the chamber 11.

On the other hand, when the centering processing of the substrate W is performed, in response to a centering command from the control unit 10, the single mover 831 moves the single contact part 81 toward the axis of rotation AX and the multi-mover 832 moves the multi-contact part 82 toward the axis of rotation AX. The center of the substrate W thereby coincides with the axis of rotation AX.

The substrate observing mechanism 9 has a light source part 91, an image pickup part 92, an observation head 93, and an observation head driver 94. The light source part 91 and the image pickup part 92 are arranged in parallel at an optical component attachment position 177 (FIG. 3) of the base member 17. In response to a lighting command from the control unit 10, the light source part 91 emits illumination light toward an observation position. This observation position is a position corresponding to the peripheral edge part Ws of the substrate W, which corresponds to a position (not shown) at which the observation head 93 is positioned.

The observation head 93 is reciprocally movable between the observation position and a separation position away from the observation position outward in a radial direction of the substrate W. The observation head driver 94 is connected to the observation head 93. The observation head driver 94 is attached to the base member 17 at a head driving position 178 (FIG. 3) of the base member 17. Then, in response to a head moving command from the control unit 10, the observation head driver 94 causes the observation head 93 to reciprocally move in a head movement direction D3 inclined at about 10° with respect to the first virtual horizontal line VL1. More specifically, while observation processing of the substrate W is not performed, the observation head driver 94 causes the observation head 93 to move to the retracted position, to be positioned. For this reason, the observation head 93 is away from the conveyance path TP, and it is thereby possible to effectively prevent interference of the observation head 93 with the substrate W loaded into or unloaded from the chamber 11. On the other hand, when the observation processing of the substrate W is performed, in response to a substrate observing command from the control unit 10, the observation head driver 94 causes the observation head 93 to move to the observation position.

When the observation head 93 having such a configuration is positioned at the observation position and the light source part 91 is lit in response to the lighting command from the control unit 10 in this positioning state, the illumination light is emitted to the lighting area of the observation head 93. The peripheral edge part Ws of the substrate W and an adjacent area thereof are thereby illuminated by diffused illumination light from the observation head 93. Further, this reflected light reflected by the peripheral edge part Ws and the adjacent area thereof is guided to the image pickup part 92 through the observation head 93.

The image pickup part 92 has an observation lens system consisting of object-side telecentric lenses and a CMOS camera. Therefore, among the reflected light guided from the observation head 93, only rays of light in parallel to the optical axis of the observation lens system enter a sensor surface of the CMOS camera and an image of the peripheral edge part Ws of the substrate W and the adjacent area thereof is formed on the sensor surface. Thus, the image pickup part 92 images the peripheral edge part Ws of the substrate W and the adjacent area thereof and acquires an upper-surface image, a side-surface image, and a lower-surface image of the substrate W. Then, the image pickup part 92 transmits image data representing these images to the control unit 10.

The control unit 10 includes an arithmetic processor 10A, a storage 10B, a reader 10C, an image processor 10D, a drive controller 10E, a communicator 10F and an exhaust controller 10G. The storage 10B is constituted by a hard disk drive or the like, and stores a program for performing the bevel processing by the substrate processing apparatus 1. This program is stored, for example, in a computer-readable recording medium RM (e.g. an optical disk, a magnetic disk, a magneto-optical disk, or the like), read from the recording medium RM by the reader 10C and saved in the storage 10B. Further, the program may be provided, for example, via an electrical communication line without being limited to provision via the recording medium RM. The image processor 10D applies various processings to an image captured by the substrate observing mechanism 9. The drive controller 10E controls each driver of the substrate processing apparatus 1. The communicator 10F conducts communication with a controller for integrally controlling each component of the substrate processing system 100 and the like. The exhaust controller 10G controls the exhaust part 38.

Further, a display unit 10H (e.g. a display and the like) for displaying various pieces of information and an input unit (e.g. a keyboard, a mouse and the like) for receiving an input from an operator are connected to the control unit 10.

The arithmetic processor 10A is constituted by a computer including a CPU (=Central Processing Unit), a RAM (=Random Access Memory) and the like, and performs the bevel processing by controlling each component of the substrate processing apparatus 1 in accordance with the program stored in the storage 10B as described below. The bevel processing by the substrate processing apparatus 1 is described below with reference to FIG. 10.

FIG. 10 is a flowchart showing bevel processing performed, as an example of a substrate processing operation, by the substrate processing apparatus shown in FIG. 2. In applying the bevel processing to the substrate W by the substrate processing apparatus 1, the arithmetic processor 10A causes the elevation drivers 71, 72 to integrally move up the lower sealing cup member 61, the nozzle head 56, the beam member 49, the support member 404 and the shielding plate structure 40. While the lower sealing cup member 61 is moving up, the projections 613 are engaged with the upper annular part 332 of the upper cup 33 and, thereafter, the upper cup 33 is moved up together with the lower sealing cup member 61, the nozzle head 56, the beam member 49, the support member 404 and the shielding plate structure 40 and positioned at the retracted position. In this way, the conveyance space sufficient to allow the entrance of the hand (not shown) of the substrate conveyor robot 111 is formed above the spin chuck 21. Further, the arithmetic processor 10A uses the centering driver 83 to move the single mover 831 and the multi-contact part 82 to the retracted position away from the spin chuck 21 and also uses the observation head driver 94 to move the observation head 93 to a waiting position away from the spin chuck 21. Among the constituent elements arranged around the spin chuck 21, as shown in FIG. 4, the nozzle head 56, the light source part 91, the image pickup part 92, the motor 23, and the multi-contact part 82 are thereby positioned on the side of the maintenance opening (the lower side in this figure) relative to the first virtual horizontal line VL1. Further, though the single mover 831 and the observation head 93 are positioned on the side of the conveyance opening 11b1 relative to the first virtual horizontal line VL1, these constituent elements are out of a moving area of the substrate W along the conveyance path TP. In the present embodiment, since such a layout structure is adopted, in loading of the substrate W into or out from the chamber 11, it is possible to effectively prevent interference of the constituent elements arranged around the spin chuck 21 with the substrate W.

After confirming the completion of the formation of the conveyance space and the prevention of interference with the substrate W, the arithmetic processor 10A gives a loading request of the substrate W to the substrate conveyor robot 111 via the communicator 10F and it is waited until an unprocessed substrate W is carried into the substrate processing apparatus 1 along the conveyance path TP shown in FIG. 4 and placed on the upper surface of the spin chuck 21. Then, the substrate W is placed on the spin chuck 21 (Step S1). Note that, at this point of time, the pump 26 is stopped and the substrate W is horizontally movable on the upper surface of the spin chuck 21.

When the loading of the substrate W is completed, the substrate conveyor robot 111 is retracted along the conveyance path TP from the substrate processing apparatus 1. Following that, the arithmetic processor 10A controls the centering driver 83 such that the single contact part 81 and the multi-contact part 82 approach the substrate W. In this way, the eccentricity of the substrate W with respect to the spin chuck 21 is eliminated and the center of the substrate W coincides with that of the spin chuck 21 (Step S2). If the centering processing is completed in this way, the arithmetic processor 10A controls the centering driver 83 to separate the single contact part 81 and the multi-contact part 82 from the substrate W and operates the pump 26 to apply a negative pressure to the spin chuck 21. In this way, the spin chuck 21 sucks and holds the substrate W from below.

Subsequently, the arithmetic processor 10A gives a move-down command to the elevation drivers 71, 72. In response to this, the elevation drivers 71, 72 integrally move down the lower sealing cup member 61, the nozzle head 56, the beam member 49, the support member 404 and the shielding plate structure 40. During these downward movements, the upper cup 33 supported from below by the projections 613 of the lower sealing cup member 61 is coupled to the lower cup 32. The rotating cup 31 (=coupled body of the upper cup 33 and the lower cup 32) is thereby formed.

After the rotating cup 31 is formed, the lower sealing cup member 61, the nozzle head 56, the beam member 49, the support member 404 and the shielding plate structure 40 are further integrally moved down, and the flange parts 611, 612 of the lower sealing cup member 61 are respectively locked by the flange part 621 of the upper sealing cup member 62 and the fixed cup 34. In this way, the lower sealing cup member 61 is positioned at the lower limit position (position in FIG. 2) (Step S3). After the above locking, the flange part 621 of the upper sealing cup member 62 and the flange part 611 of the lower sealing cup member 61 are held in close contact via the O-ring 63, and the flange part 612 of the lower sealing cup member 61 and the fixed cup 34 are held in close contact through the O-ring 63. As a result, as shown in FIG. 2, the lower sealing cup member 61 and the fixed cup 34 are connected in the vertical direction, and the sealed space 12a is formed by the upper sealing cup member 62, the lower sealing cup member 61 and the fixed cup 34, and the sealed space 12a is separated from the outside atmosphere (outside space 12b) (atmosphere separation).

In this atmosphere separated state, the lower surface of the shielding plate structure 40 covers a surface region excluding the peripheral edge part Ws, out of the upper surface Wf of the substrate W, from above. Further, the upper surface nozzles 51F are positioned in such a posture that the discharge ports 511 are facing the peripheral edge part of the upper surface Wf of the substrate W in the cut 425 of the shielding plate structure 40. When preparation for the supply of the processing liquids to the substrate W is thus completed, the arithmetic processor 10A gives a rotation command to the motor 23 to start the rotation of the spin chuck 21 holding the substrate W and the rotating cup 31 (Step S4). Rotating speeds of the substrate W and the rotating cup 31 are set, for example, at 1800 rpm. Further, the arithmetic processor 10A controls the drive of the heater driver 402 to raise respective temperatures of the peripheral edge heater 44 and the central heater 45 to respective desired temperatures.

Next, the arithmetic processor 10A gives a heated gas supply command to the heated gas supplier 47. The nitrogen gas heated by the heater 471, i.e., the heated gas is thereby fed under pressure from the heated gas supplier 47 toward the upper surface protecting/heating mechanism 4 (Step S5). This heated gas is heated by the ribbon heater 48 during passing through the pipe 46. The heated gas is thereby supplied to the upper surface protecting/heating mechanism 4 while preventing reduction in the temperature during the gas supply through the pipe 46. Further, in the upper surface protecting/heating mechanism 4, the heated gas flowing in the clearance region 403 is heated by the peripheral edge heater 44 and the central heater 45. This heated gas which is heated thus is discharged toward a space SPa (see FIG. 6) sandwiched between the substrate W and the shielding plate structure 40 in the vicinity of the peripheral edge part of the substrate W. The peripheral edge part Ws of the upper surface Wf of the substrate W is thereby intensively heated. Furthermore, the peripheral edge part Ws of the substrate W is also heated by the peripheral edge heater 44. For this reason, the temperature of the peripheral edge part Ws of the substrate W rises with the passage of time and reaches a temperature suitable for the bevel processing, e.g. 90° C. Further, the temperature of the substrate W other than the peripheral edge part Ws also rises to a temperature which is substantially equal thereto by receiving heat from the central heater 45. In other words, in the present embodiment, the inplane temperature of the upper surface Wf of the substrate W is substantially uniform. Therefore, it is thereby possible to effectively suppress warp of the substrate W.

Following this, the arithmetic processor 10A supplies the processing liquids to the upper surface nozzles 51F and the lower surface nozzles 51B by controlling the processing liquid suppliers 52. That is, flows of the processing liquids are discharged from the upper surface nozzles 51F to contact the peripheral edge part of the upper surface of the substrate W, and flows of the processing liquids are discharged from the lower surface nozzles 51B to contact the peripheral edge part of the lower surface of the substrate W. In this way, the bevel processing is performed on the peripheral edge part Ws of the substrate W (Step S6). Upon detecting the passage of a processing time required for the bevel processing of the substrate W, the arithmetic processor 10A gives a supply stop command to the processing liquid suppliers 52 to stop the discharge of the processing liquids.

Following that, the arithmetic processor 10A gives a supply stop command to the nitrogen gas supplier 47 to stop the supply of the heated gas from the nitrogen gas supplier 47 toward the shielding plate structure 40 (Step S7). Further, the arithmetic processor 10A gives a rotation stop command to the rotation driver 23 to stop the rotation of the spin chuck 21 and the rotating cup 31 (Step S8).

In next Step S9, the arithmetic processor 10A observes the peripheral edge part Ws of the substrate W to inspect a result of the bevel processing. More specifically, the arithmetic processor 10A positions the upper cup 33 at the retracted position to form the conveyance space in the same manner as that during the loading of the substrate W. Then, the arithmetic processor 10A controls the observation head driver 94 to bring the observation head 93 closer to the substrate W. Then, the arithmetic processor 10A lights the light source part 91 to illuminate the peripheral edge part Ws of the substrate W through the observation head 93. Further, the image pickup part 92 receives the reflected light which is reflected by the peripheral edge part Ws and the adjacent area, to thereby image the peripheral edge part Ws and the adjacent area. Specifically, a peripheral-edge-part image of the peripheral edge part Ws along the rotation direction of the substrate W is acquired out of a plurality of images of the peripheral edge part Ws acquired by the image pickup part 92 while the substrate W is rotated about the axis of rotation AX. Then, the arithmetic processor 10A controls the observation head driver 94 to retract the observation head 93 from the substrate W. In parallel with this, the arithmetic processor 10A inspects whether or not the bevel processing has been satisfactorily performed, on the basis of the picked-up image of the peripheral edge part Ws and the adjacent area, i.e., the peripheral-edge-part image. Further, in the present embodiment, as an example of the inspection, a processing width is inspected from the peripheral-edge-part image, which is processed by using the processing liquids, from the end surface of the substrate W toward the central part of the substrate W (inspection after processing).

After the inspection, the arithmetic processor 10A gives an unloading request of the substrate W to the substrate conveyor robot 111 via the communicator 10F, and the processed substrate W is unloaded from the substrate processing apparatus 1 (Step S10). Further, this series of steps is repeatedly performed.

In the above-described present embodiment, the heated gas corresponds to one example of a “gas” of the present invention. Further, the peripheral edge heater 44 and the central heater 45 correspond to one example of a “peripheral edge heating part” of the present invention and one example of a “central heating part” of the present invention, respectively.

Thus, in the present embodiment, the annular air outlet 401 is formed in the vicinity of the peripheral edge part of the upper surface Wf of the substrate W, and the heated gas is directly supplied from the annular air outlet 401 to the vicinity of the peripheral edge part of the substrate W. For this reason, as compared with the proposed technique which causes the heated gas supplied to the central part of the upper surface Wf of the substrate W to flow to the peripheral edge part Ws of the substrate W along the upper surface Wf of the substrate W, it is possible to efficiently raise the temperature of the peripheral edge part Ws of the substrate W. Therefore, it is possible to heat the peripheral edge part Ws of the substrate W with the heated gas which is less. As a result, the amount of heated gas to be used can be reduced, and the environmental load is thereby reduced.

Further, as the heating means for further heating the heated gas flowing in the clearance region 403, the peripheral edge heater 44 is provided in the first under block 42. Specifically, the heated gas is further heated immediately before being supplied from the annular air outlet 401. For this reason, the high-temperature heated gas is supplied from the annular air outlet 401 to the peripheral edge part Ws of the upper surface Wf of the substrate W. Moreover, the peripheral edge part Ws of this substrate W is heated by not only the above-described heated gas but also the peripheral edge heater 44. Therefore, as compared with the proposed technique, it is possible to raise the temperature of the peripheral edge part Ws of the substrate W to a temperature suitable for the substrate processing in a short time.

Furthermore, in the above-described embodiment, besides the peripheral edge heater 44, the central heater 45 is provided. For this reason, it is possible to keep the inplane temperature of the upper surface Wf of the substrate W uniform and effectively suppress warp of the substrate W. Further, it is possible to appropriately respond to a case where the substrate W already has a warp. By individually adjusting respective heater outputs of the peripheral edge heater 44 and the central heater 45 for the substrate W having a warp, there arises a temperature difference between at the vicinity of the center of the substrate W and at the vicinity of the peripheral edge part thereof. By using the temperature difference, it is possible to individually control the thermal expansion amount of each component. In other words, it becomes possible to reduce the warp of the substrate W by adjusting the heater output.

Furthermore, in the above-described embodiment, the clearance region 403 is constituted of an inclined portion sandwiched between the base block 41 and the second under block 43 and a vertical portion sandwiched between the first under block 42 and the second under block 43. Specifically, a flowing path of the heated gas is gently changed from the inclined portion to the vertical portion. Therefore, it is possible to suppress pressure loss of the heated gas at a connection portion of the inclined portion and the vertical portion and reduce the temperature decrease of the heated gas.

Moreover, in the above-described embodiment, as shown in FIGS. 3 and 4, the heater 471 for obtaining the heated gas to heat the substrate W is attached to the outer wall (sidewall 11e) of the chamber 11. In other words, the heater 471 is provided outside the chamber 11. Therefore, it is possible to prevent the heat generated by the heater 471 from affecting various mechanisms disposed in the internal space 12 of the chamber 11. Especially, since the light source part 91 and the image pickup part 92 are susceptible to the effect of heat, in the present embodiment, the light source part 91 and the image pickup part 92 are arranged at the separation position away from the attachment portion of the heater 471. Therefore, by adopting the above-described layout structure, the light source part 91 and the image pickup part 92 become less susceptible to the effect of heat generated by the heater 471. As a result, it is possible to prevent the reduction in the observation accuracy due to the effect of temperature change and further possible to observe the peripheral edge part of the substrate with high accuracy. Further, regarding the effect of heat from the heater 471, since the processing liquid discharge nozzles 51F and 51B are also susceptible thereto, the processing liquid discharge nozzles 51F and 51B are arranged at the separation position away from the attachment portion of the heater 471. In more detail, as shown in FIG. 4, the light source part 91, the image pickup part 92, and the processing liquid discharge nozzles 51F and 51B are arranged on the opposite side of the heater 471 with respect to the second virtual horizontal line VL2 in a plan view of the chamber 11 viewed from above. By adopting such an arrangement structure, the respective distances from the heater 471 to the light source part 91, the image pickup part 92, and the processing liquid discharge nozzles 51F and 51B are increased, and it is possible to reliably suppress the effect of heat from the heater 471.

Further, the present invention is not limited to the above-described embodiment and numerous modifications and variations can be added to those described above without departing from the scope of the invention. In the above-described embodiment, for example, the present invention is applied to the substrate processing apparatus 1 having the rotating cup 31. Furthermore, in the above-described embodiment, the present invention is applied to a substrate processing apparatus having a raised floor structure in which the substrate processing part SP is installed on the upper surface of the base member 17. Further, in the above-described embodiment, the present invention is applied to the substrate processing apparatus 1 having the atmosphere separating mechanism 6, the centering mechanism 8, and the substrate observing mechanism 9. The present invention, however, can be applied to a substrate processing apparatus not having any of these configurations, i.e., a substrate processing apparatus which processes the peripheral edge part of the substrate W by supplying a processing liquid to the above-described peripheral edge part of the substrate W.

Furthermore, though the peripheral edge heater 44 is sandwiched between the annular member 421 and the annular member 422 in the above-described embodiment, the arrangement position of the peripheral edge heater 44 in the first under block 42 is not limited to this position. Further, though the central heater 45 is sandwiched between the disk member 431 and the intermediate member 432 in the above-described embodiment, the arrangement position of the central heater 45 in the second under block 43 is not limited to this position.

Furthermore, though the first under block 42 is formed of two members (=the annular member 421 +the annular member 422) in the above-described embodiment, the first under block 42 may be formed of a single member or may be formed of three or more members. Though the second under block 43 is formed of three members (=the disk member 431+the intermediate member 432+the truncated cone member 433), the second under block 43 may be formed of a single member or may be formed of two or four or more members.

Further, though the present invention is applied to the substrate processing apparatus which performs the bevel processing as one example of “substrate processing”, the present invention is applicable to substrate processing apparatuses in general for performing substrate processing on a substrate by supplying a processing liquid to a peripheral edge part of the substrate being rotated.

Although the invention has been described by way of the specific embodiments above, this description is not intended to be interpreted in a limited sense. By referring to the description of the invention, various modifications of the disclosed embodiments will become apparent to a person skilled in this art similarly to other embodiments of the invention. Hence, appended claims are thought to include these modifications and embodiments without departing from the true scope of the invention.

### INDUSTRIAL APPLICABILITY

The present invention is applicable to a substrate processing apparatus in general that processes a peripheral edge part of a substrate with a processing liquid.

### REFERENCE SIGNS LIST

1 . . . substrate processing apparatus
2A . . . substrate holder
2B . . . rotating mechanism
4 . . . upper surface protecting/heating mechanism
5 . . . processing mechanism
40 . . . shielding plate structure
41 . . . base block
42 . . . first under block
43 . . . second under block
44 . . . peripheral edge heater (peripheral edge heating part)
45 . . . central heater (central heating part)
401 . . . annular air outlet
403 . . . clearance region
414 . . . funnel-like space
AX . . . axis of rotation
Wf . . . upper surface (of substrate)
Ws . . . peripheral edge part (of substrate)
Z . . . vertical direction

1. A substrate processing apparatus, comprising:
a substrate holder provided rotatably about an axis of rotation extending in a vertical direction while holding a substrate in a substantially horizontal posture;
a rotating mechanism configured to rotate the substrate holder about the axis of rotation;
a processing mechanism configured to perform substrate processing on a peripheral edge part of the substrate by supplying a processing liquid to a peripheral edge part of an upper surface of the substrate held by the substrate holder rotated by the rotating mechanism; and
an upper surface protecting/heating mechanism configured to heat the substrate while being configured to cover the upper surface of the substrate held by the substrate holder, wherein
the upper surface protecting/heating mechanism includes:
a base block in which a first opening is provided at a central part of an upper surface thereof, a second opening wider than the first opening is provided at a central part of an upper surface thereof, and a funnel-like space having an inner diameter which becomes larger as it goes downward from the first opening and is connected to the second opening;
a first under block, in which a third opening having the same shape as the second opening is provided with at a central part of an upper surface thereof, and a penetration space is formed so as to penetrate from the third opening toward a central part of a lower surface thereof and has a hollow shape, being coupled to the base block in a state where the third opening coincides with the second opening and a lower surface of a peripheral edge part thereof faces the peripheral edge part of the upper surface of the substrate;
a peripheral edge heating part provided in the first under block; and
a second under block coupled to the base block with the lower surface thereof facing a central part of the upper surface of the substrate while being loosely inserted into the penetration space and the funnel-like space,
an annular air outlet formed between the lower surface of the first under block and the lower surface of the second under block in the vicinity of the peripheral edge part of the upper surface of the substrate is connected to the first opening through a clearance region between the base block and the first under block and the second under block, and
the peripheral edge heating part heats the gas flowing in the clearance region and heats the peripheral edge part of the upper surface of the substrate.

2. The substrate processing apparatus according to claim 1, wherein
the substrate holder is a spin chuck made of resin, with an upper surface thereof adsorbing a central part of a lower surface of the substrate to thereby hold the substrate.

3. The substrate processing apparatus according to claim 2, wherein
the upper surface of the spin chuck is narrower than the lower surface of the second under block and positioned vertically below the lower surface of the second under block in a horizontal plane.

4. The substrate processing apparatus according to claim 1 further comprising:
a central heating part provided in the second under block and configured to heat the gas flowing in the clearance region and the central part of the substrate.

5. The substrate processing apparatus according to claim 4, wherein
the amount of heat generation of the peripheral edge heating part and that of the central heating part are adjustable independently of each other.

6. The substrate processing apparatus according to claim 5, wherein
the amount of heat generation of the peripheral edge heating part is higher than that of the central heating part.
